(19) United States
(12) Patent Application Publication
(10) Pub. No.: US 2026/0175359 A1
(43) Pub. Date: Jun. 25, 2026

(54) PROCESSING METHOD, CHIP MANUFACTURING METHOD, AND DRESSING MEMBER

(71) Applicant: DISCO CORPORATION, Tokyo (JP)

(72) Inventor: Yusuke IMAIZUMI, Tokyo (JP)

(21) Appl. No.: 19/230,366

(22) Filed: Jun. 6, 2025

(30) Foreign Application Priority Data
Dec. 25, 2024 (JP) 2024-228652

(51) Int. Cl. B24B 53/12; B24B 7/22; B24B 27/06; H01L 21/78

(52) U.S. Cl. CPC B24B 53/12; B24B 7/228; B24B 27/0683; H10P 54/00

(57) ABSTRACT

A processing method includes: holding a workpiece on a holding surface of a holding table; processing the workpiece by a grindstone tool; and dressing the grindstone tool by bringing a dressing member into contact with the grindstone tool while feeding the dressing member in a stretching direction, the dressing member containing abrasive grains and linearly stretching.

### CROSS-REFERENCE TO RELATED APPLICATIONS

This application is based on and claims priority under 35 USC 119 from Japanese Patent Application No. 2024-228652 filed on Dec. 25, 2024, the contents of which are incorporated herein by reference.

### TECHNICAL FIELD

The present disclosure relates to a processing method, a chip manufacturing method, and a dressing member.

### BACKGROUND

A wafer including a plurality of devices such as integrated circuits (ICs) and large scale integrations (LSIs) partitioned by planned dividing lines on a front surface is divided into individual device chips by a cutting apparatus to be used for electrical equipment such as mobile phones and personal computers.

For example, a cutting apparatus includes a chuck table configured to hold a wafer, a cutting unit including a rotatable cutting blade configured to cut the wafer held on the chuck table, and a feeding unit configured to processing-feed the chuck table and the cutting unit relative to each other, and divides the wafer into individual device chips (for example, see Japanese Patent Application Laid-Open Publication No. 2007-203429 and Japanese Patent Application Laid-Open Publication No. 2015-216324).

Such a cutting apparatus performs dressing including sharpening and shaping of the cutting blade, when a cutting ability of the cutting blade is reduced.

In the cutting apparatus described in Patent Literature 1, it is necessary to carry in and out a dressing board relative to the chuck table, and thus it may take time and effort to dress the cutting blade.

In the cutting apparatus described in Patent Literature 2, a dressing board is also installed on a frame support portion of the chuck table, it is necessary to replace the dressing board at any time, and may take time and effort to dress the cutting blade.

The present disclosure relates to a processing method, a chip manufacturing method, and a dressing member that can perform a dressing step without taking time or effort.

### SUMMARY

A first aspect of the present disclosure relates to a processing method including: holding a workpiece on a holding surface of a holding table; processing the workpiece by a grindstone tool; and dressing the grindstone tool by bringing a dressing member into contact with the grindstone tool while feeding the dressing member in a stretching direction, the dressing member containing abrasive grains and linearly stretching.

A second aspect of the present disclosure relates to a chip manufacturing method for dividing a substrate into a plurality of chips, the substrate including devices formed in respective regions partitioned by a plurality of planned dividing lines. The chip manufacturing method includes: holding the substrate on a holding table; cutting the substrate along the planned dividing lines by a cutting blade including a grindstone; and dressing the cutting blade by bringing a dressing member into contact with the cutting blade while feeding the dressing member in a stretching direction, the dressing member containing abrasive grains and linearly stretching.

A third aspect of the present disclosure relates to a chip manufacturing method for dividing a substrate into a plurality of chips, the substrate including devices formed in respective regions partitioned by a plurality of planned dividing lines. The chip manufacturing method includes: holding the substrate on a holding table; grinding the substrate by a grinding wheel including a grindstone; dressing the grinding wheel by bringing a dressing member into contact with the grinding wheel while feeding the dressing member in a stretching direction, the dressing member containing abrasive grains and linearly stretching; and cutting the substrate along the planned dividing lines by a cutting blade.

A fourth aspect of the present disclosure relates to a dressing member for dressing a grindstone tool. The dressing member contains abrasive grains at least on an outer surface, the dressing member has a linearly stretching shape, and the dressing member dresses the grindstone tool when the outer surface is brought into contact with the grindstone tool.

### BRIEF DESCRIPTION OF DRAWINGS

Exemplary embodiments of the present disclosure will be described in detail based on the following figures, wherein

FIG. 1 is a perspective view of a wafer including a plurality of devices on a front surface;

FIG. 2 illustrates a state when the wafer is cut by a cutting apparatus;

FIG. 3 is a flowchart showing an example of a processing method according to a first embodiment;

FIG. 4 illustrates an example of a dressing step for a cutting blade;

FIG. 5 illustrates another example of the dressing step for the cutting blade;

FIG. 6 is a perspective view of a cutting apparatus including a dressing mechanism according to modification;

FIG. 7 illustrates a state when a grinding apparatus grinds a wafer;

FIG. 8 is a flowchart showing an example of a processing method according to a second embodiment; and

FIG. 9 illustrates an example of a dressing step for a grinding wheel.

### DESCRIPTION OF EMBODIMENTS

Embodiments of a processing method, a chip manufacturing method, and a dressing member of the present disclosure are described below with reference to the accompanying drawings.

### First Embodiment

A first embodiment of the processing method of the present disclosure is described. The processing method according to the first embodiment is to cut a workpiece, such that the workpiece is divided to manufacture chips.

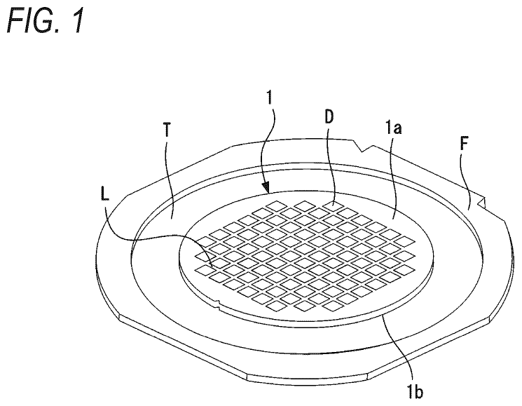

First, a wafer 1 (example of a workpiece) to be processed by the processing method is described. FIG. 1 is a perspective view of the wafer 1 including a plurality of devices D on a front surface 1a.

The wafer 1 is a substrate made of a material such as silicon, silicon carbide (SiC), and other semiconductors, or a material such as sapphire, glass, and quartz.

The front surface of the wafer 1 is partitioned into a plurality of regions by a plurality of intersecting planned dividing lines (streets) L, and the devices D such as integrated circuits (ICs) and large scale integrations (LSIs) are formed in the partitioned regions.

Finally, the wafer 1 is divided along the planned dividing lines L to form individual chips.

A tape T is affixed to a metal frame F on a back surface 1b of the wafer 1. The wafer 1 is cut in a state of a frame unit integrated with the tape T and the frame F.

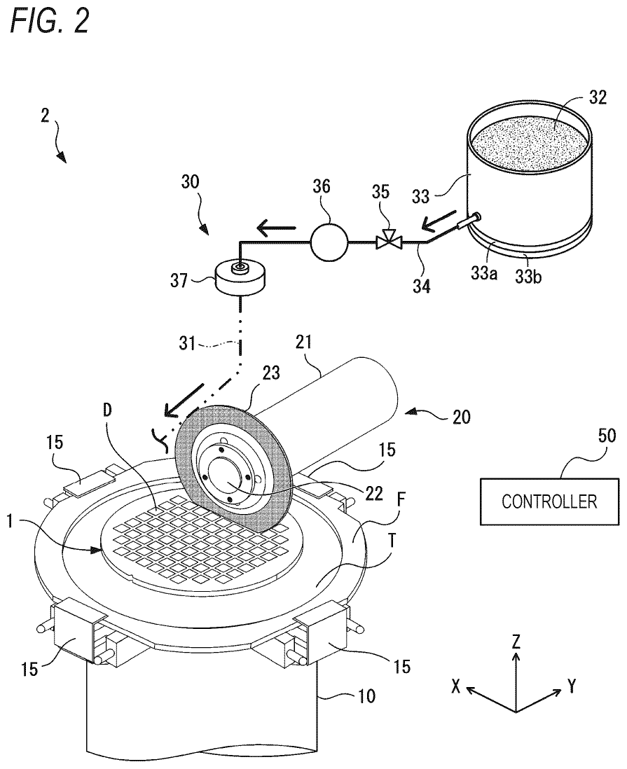

FIG. 2 illustrates a state when a cutting apparatus 2 cuts the wafer 1. The cutting apparatus 2 includes a chuck table 10 that holds the wafer 1 in a state of a frame unit, a cutting unit 20 that includes a cutting blade 23 and cuts and divides the wafer 1 held by the chuck table 10 into a plurality of chips, a dressing mechanism 30 that dresses the cutting blade 23, and a controller 50 that controls elements of the cutting apparatus 2.

The chuck table 10 has a disk-shaped holding surface that holds the wafer 1 on an upper surface, and the wafer 1 placed on the holding surface is held under suction by a suction source (not illustrated). Around the chuck table 10, a plurality of (four in the illustrated example) clamp units 15 are arranged at equal intervals along a circumferential direction of the chuck table 10. The clamp units 15 fix the frame F placed on the chuck table 10.

The chuck table 10 is rotatable, by a spindle, a motor, and the like, about a central axis extending in a direction (vertical direction) orthogonal to the holding surface. The chuck table 10 is further movable, for example, in an X direction (horizontal direction) in the drawing by a moving unit such as a ball screw and a motor. The chuck table 10 may also be movable along, for example, a Y direction (direction orthogonal to the X direction of the horizontal direction) and a Z direction (vertical direction) in the drawing.

The cutting unit 20 includes a spindle housing 21, a spindle 22 supported inside the spindle housing 21, and the cutting blade 23 mounted on a top end of the spindle 22.

The spindle housing 21 has a cylindrical shape and is disposed such that a longitudinal direction thereof coincides with the horizontal direction. A top end portion of the spindle housing 21 is open, from which a top end portion of the spindle 22 protrudes.

The spindle 22 has a columnar shape and is disposed such that a longitudinal direction thereof coincides with the horizontal direction. The spindle 22 is rotatably accommodated in the spindle housing 21. A rotary drive source such as a motor is provided in a vicinity of a base end portion of the spindle 22.

The cutting blade 23 includes, on an outer periphery, a cutting edge (grindstone) in which abrasive grains including diamond, cubic boron nitride (CBN), and the like are dispersed and fixed by a binder made of resin or metal such as nickel. The cutting blade 23 is an example of a grindstone tool. The cutting blade 23 may be a hub blade having a hub base, or a hubless blade having no hub base. Although not illustrated, the cutting apparatus 2 is provided with a cutting water supply nozzle that supplies cutting water to a front surface side and a back surface side of the cutting blade 23, and the cutting water is supplied during cutting.

The cutting unit 20 is movable along, for example, the Y direction and the Z direction in the drawing by a moving unit such as a ball screw and a motor. The cutting unit 20 may be movable along the X direction in the drawing.

During cutting, the cutting unit 20 places the cutting blade 23 by the moving unit on an extension line of the planned dividing line L of the wafer 1, and rotates the cutting blade 23 while supplying cutting water. In this state, the chuck table 10 moves along the X direction, so that the cutting blade 23 cuts the wafer 1 along the planned dividing line L. When cutting is finished along one planned dividing line L, the cutting unit 20 moves the cutting blade 23 in the Y direction (dividing-feed direction) and places the cutting blade 23 on an extension line of the adjacent planned dividing line L to cut the wafer 1 along the planned dividing line L.

The dressing mechanism 30 includes a dressing member 31 that contains abrasive grains and linearly stretches. The dressing mechanism 30 dresses the cutting blade 23 by bringing the dressing member 31 into contact with the cutting blade 23 while feeding the dressing member 31 in a stretching direction.

The dressing mechanism 30 according to the present embodiment includes a reservoir 33 that stores a fluid 32 obtained by kneading abrasive grains into a fluid binder, a flow path 34 such as a tube connected to the reservoir 33, an on-off valve 35 and a pump 36 that are provided on the flow path 34, and a dressing member generator 37 that generates the dressing member 31 from the fluid 32 fed from the reservoir 33.

The binder used to obtain the fluid 32 can be selected from, for example, a thermoplastic resin and a gelling agent.

Preferred examples of the thermoplastic resin include polyethylene, polypropylene, polyvinyl chloride, polystyrene, polyvinyl acetate, polyurethane, ABS resin, AS resin, acrylic resin, polylactic acid, polyetherimide, polyamide nylon, polyacetal, polycarbonate, modified polyphenylene ether, polyethylene terephthalate, polybutylene terephthalate, cyclic polyolefin, polyphenylene sulfide, polytetrafluoroethylene, polysulfone, polyether sulfone, amorphous polyarylate, liquid crystal polymer, polyether ether ketone, thermoplastic polyimide, and polyamideimide.

Preferred examples of the gelling agent include pectin, guar gum, xanthan gum, tamarind gum, carrageenan, propylene glycol, carboxymethyl cellulose, gelatin, and agar.

The abrasive grains contained in the fluid 32 can be selected from, for example, silicon carbide, alumina, and diamond.

The reservoir 33 is provided with a heater (for example, a Peltier element) 33a that heats the fluid 32 and a vibrator (for example, a piezoelectric element) 33b that applies vibration to the reservoir 33 to stir the fluid 32 as necessary for a purpose of appropriately maintaining fluidity of the stored fluid 32.

The fluid 32 stored in the reservoir 33 is pressure-fed to the dressing member generator 37 by operating the pump 36 and opening the on-off valve 35. A timing and a flow rate at which the fluid 32 is pressure-fed are freely set. A configuration for feeding the fluid 32 from the reservoir 33 to the dressing member generator 37 is not limited thereto, and for example, the pump 36 may not be provided in the flow path 34. Specifically, the fluid 32 may be fed from the reservoir 33 to the dressing member generator 37 by sealing the reservoir 33 and disposing an air pump that introduces high-pressure air into the reservoir 33.

The dressing member generator 37 is provided downstream of the pump 36 on the flow path 34, and cools and solidifies the fluid 32 fed from the reservoir 33 to generate the linearly (in other words, in a wire shape) stretching dressing member 31. The dressing member generator 37 includes, for example, a Peltier element.

The dressing member 31 generated by the dressing member generator 37 contains abrasive grains at least on an outer surface (outer peripheral surface 31a and distal end 31b described later). The dressing member 31 is formed of a flexible material, and is thus deformable.

The dressing member 31 generated by the dressing member generator 37 is guided to the cutting blade 23 via a guide mechanism such as a roller (not illustrated). Since the dressing member 31 is deformable, a degree of freedom in routing the dressing member 31 from the dressing member generator 37 to the cutting blade 23 is high.

A tension is appropriately applied to the dressing member 31 guided to the cutting blade 23, and the dressing member 31 with the tension applied thereto comes into contact with the cutting blade 23.

The dressing member 31 is preferably movable integrally with the cutting unit 20. According to such a configuration, the dressing member 31 can move along with movement of the cutting unit 20 in the Y direction and the Z direction. According to such a configuration, the dressing member 31 can move while maintained in contact with the cutting blade 23.

In this way, since the cutting apparatus 2 includes the dressing mechanism 30, it is not necessary to carry a dressing board into or out of the cutting apparatus 2 when dressing the cutting blade 23. Therefore, the cutting blade 23 can be dressed without taking time or effort.

The controller 50 includes, for example, a processor (for example, a central processing unit (CPU)) and a storage device including a main storage device (for example, a volatile memory) and an auxiliary storage device (for example, a nonvolatile memory). The controller 50 controls operations of components of the cutting apparatus 2 by operating the processor in accordance with a program stored in advance.

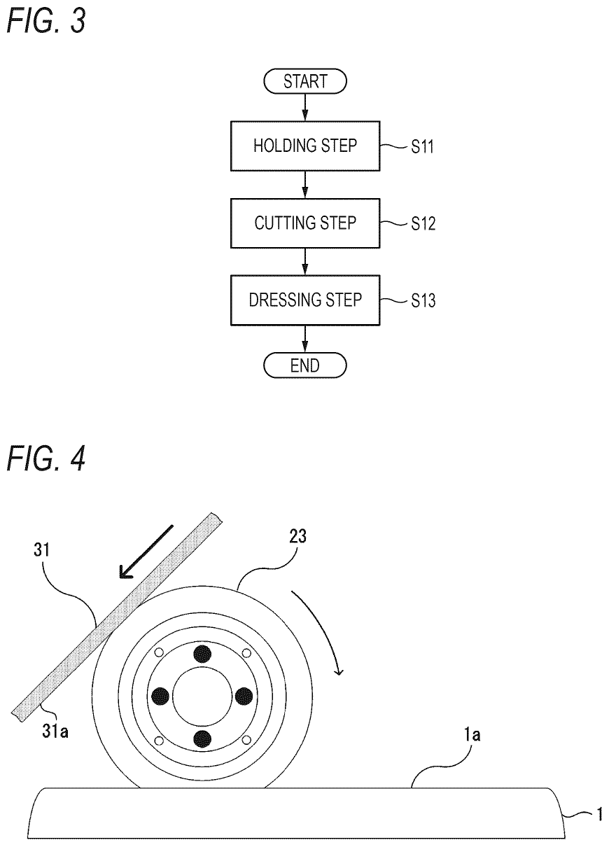

FIG. 3 is a flowchart illustrating an example of the processing method according to the first embodiment. The processing method according to the first embodiment includes a holding step S11 of holding the wafer 1 on the holding surface of the chuck table 10, a cutting step S12 of cutting the wafer 1 along the planned dividing lines L by the cutting blade 23 to divide the plurality of devices D formed on the wafer 1 into a plurality of chips, and a dressing step S13 of dressing the cutting blade 23 by bringing the cutting blade 23 into contact with the dressing member 31.

In the dressing step S13, the linearly stretching dressing member 31 is brought into contact with the cutting blade 23 while being fed in the stretching direction.

FIG. 4 illustrates an example of the dressing step S13. In the dressing step S13 in the example illustrated in FIG. 4, the outer peripheral surface 31a of the dressing member 31 extending in the stretching direction is brought into contact with the cutting blade 23. The dressing member 31 stretches along a tangential direction of the cutting blade 23 and comes into contact with the cutting blade 23. According to such a configuration, a contact area between the dressing member 31 and the cutting blade 23 can be relatively large, and thus the cutting blade 23 can be stably dressed.

In the example illustrated in FIG. 4, a feeding direction of the dressing member 31 at a contact part between the dressing member 31 and the cutting blade 23 may be set at a direction opposite to a rotation direction of the cutting blade 23. Accordingly, a dressing performance can be improved.

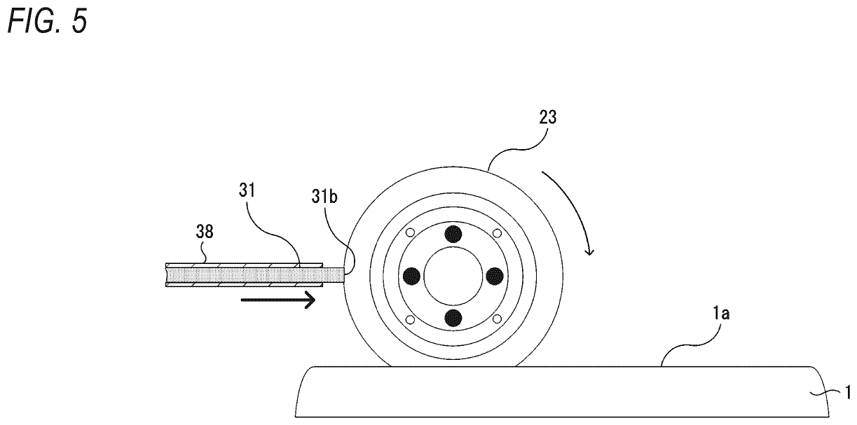

FIG. 5 illustrates another example of the dressing step S13. In the dressing step S13 in the example illustrated in FIG. 5, the distal end 31b of the dressing member 31 is brought into contact with the cutting blade 23. The dressing member 31 is guided to the cutting blade 23 through, for example, a pipe 38 routed to a vicinity of the cutting blade 23.

In this way, in the dressing step S13, the cutting blade 23 is dressed while feeding the dressing member 31 in the stretching direction, and thus it does not take time or effort to replace the dressing member 31 as compared with a case where dressing is performed by carrying in and out a dressing board. Further, the cutting blade 23 can be always dressed by the additionally fed dressing member 31.

Further, in the dressing step S13, since the linearly stretching dressing member 31 is brought into contact with the cutting blade 23 while being fed in the stretching direction, the dressing step S13 can be performed during the cutting step S12. Therefore, time required for dressing the cutting blade 23 can be substantially zero.

When the dressing step S13 is performed during the cutting step S12, a feed speed of the dressing member 31 may be changed in the dressing step S13 based on a processing status of the cutting step S12. For example, when clogging occurs in the cutting blade 23 and a drive current value for rotating the cutting blade 23 increases during the dressing step S13 and the cutting step S12, the controller 50 can change the feed speed of the dressing member 31 to eliminate the clogging of the cutting blade 23. In this way, the wafer 1 can be appropriately dressed based on the processing status of the cutting step S12, and a processing quality can be kept constant.

During the dressing step S13, a part of the dressing member 31 scatters but is flowed and collected by cutting water ejected from a cutting water supply nozzle (not illustrated).

### Modification

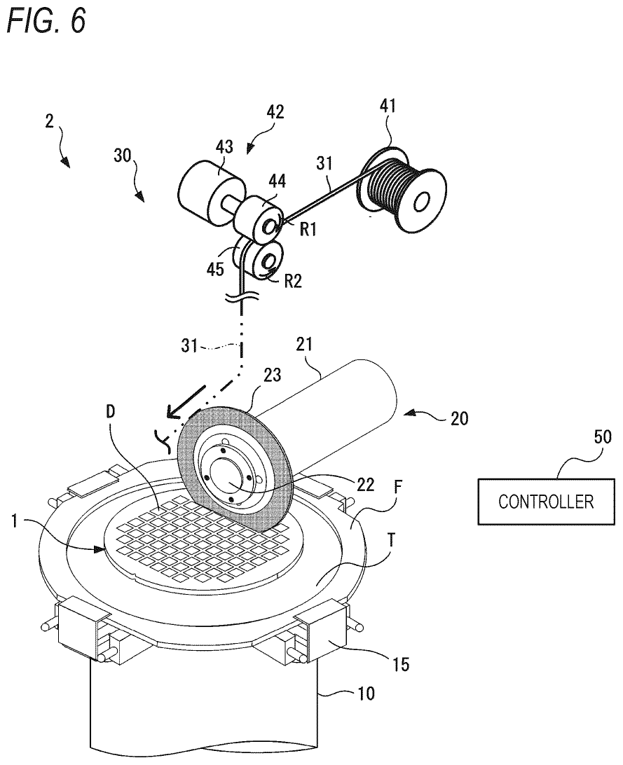

FIG. 6 is a perspective view of the cutting apparatus 2 including the dressing mechanism 30 according to modification. Configurations of the chuck table 10, the cutting unit 20, and the controller 50 are the same as those in the above-described example, and thus description thereof is omitted.

The dressing mechanism 30 according to the modification includes a reel 41 around which the dressing member 31 is wound, and a feeding unit 42 that feeds the dressing member 31 from the reel 41. Similarly to the above-described example, the dressing member 31 contains abrasive grains and has a linearly stretching shape. In the present modification, the dressing member 31 generated in advance at a place different from the cutting apparatus 2 is attached to the cutting apparatus 2 in a state of being wound around the reel 41.

As described above, since the dressing member 31 is formed of a flexible material and is deformable, the dressing member 31 can be managed in a state of being wound around the reel 41.

The feeding unit 42 includes a drive motor 43, a drive roller 44 disposed at a top end of a rotation shaft of the drive motor 43, and a guide roller 45 that rotates in contact with the drive roller 44. The dressing member 31 drawn out from the reel 41 is fed in the stretching direction by the drive roller 44 and the guide roller 45, and is guided to the cutting blade 23 via a guide mechanism such as a roller (not illustrated).

Specifically, the dressing member 31 drawn from the reel 41 is sandwiched between the drive roller 44 and the guide roller 45. When the dressing member 31 is fed in the stretching direction, the controller 50 operates the drive motor 43 to rotate the drive roller 44 in a direction indicated by an arrow R1. When the drive roller 44 rotates in the direction indicated by the arrow R1, the guide roller 45 rotates in a direction indicated by an arrow R2, and the dressing member 31 is fed toward the cutting blade 23.

Since the cutting blade 23 is also dressed while feeding the dressing member 31 in the stretching direction by the dressing mechanism 30 according to the modification, it does not take time or effort to replace the dressing member 31. Further, the cutting blade 23 can be always dressed by the additionally fed dressing member 31.

### Second Embodiment

A second embodiment of the processing method of the present disclosure is described. In the processing method according to the second embodiment, a workpiece is thinned. The thinning processing includes grinding processing and/or polishing processing, and the grinding processing is described here as an example.

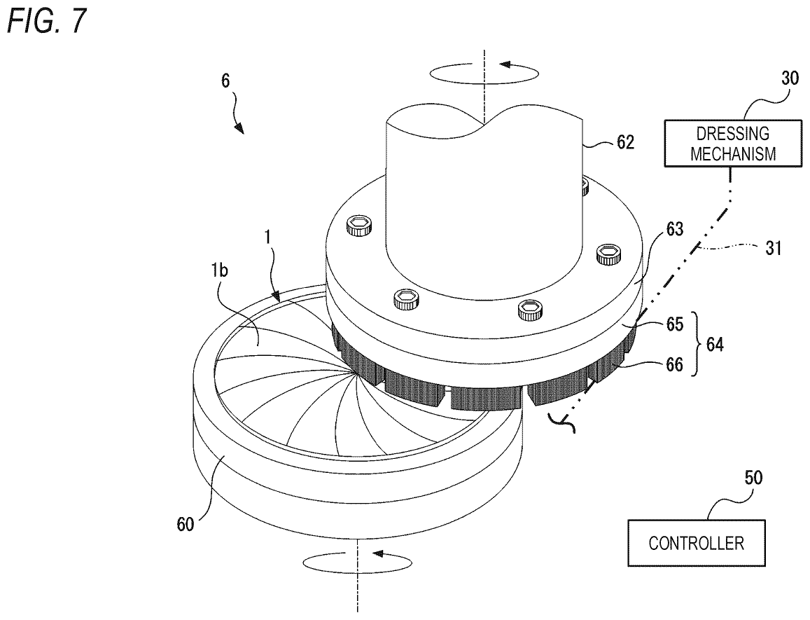

FIG. 7 illustrates a state when a grinding apparatus 6 grinds a wafer. The grinding apparatus 6 includes, for example, a chuck table 60 that holds the wafer 1 on a holding surface with the back surface 1b facing upward, a spindle 62 extending in a vertical direction and rotatable by a drive source such as a motor, a disk-shaped mount 63 fixed to a lower end of the spindle 62, and a grinding wheel 64 fixed to a lower end of the mount 63. The spindle 62 is movable up and down in the vertical direction relative to the chuck table 60.

The grinding wheel 64 includes an annular wheel base 65 made of a metal material such as stainless steel and aluminum, and a plurality of grindstones 66 annularly arranged on a lower surface of the wheel base 65. The grindstones 66 contain a binder formed of ceramics, resin, a metal material, and the like, and numerous abrasive grains such as diamond dispersed and fixed in the binder. The grinding wheel 64 is an example of a grindstone tool.

The grinding apparatus 6 further includes the dressing mechanism 30 and the controller 50 described above, and the dressing mechanism 30 dresses the grindstones 66 of the grinding wheel 64. Since the grinding apparatus 6 includes the dressing mechanism 30, it is not necessary to carry a dressing board into or out of the grinding apparatus 6 when dressing the grinding wheel 64. Therefore, the grinding wheel 64 can be dressed without taking time or effort.

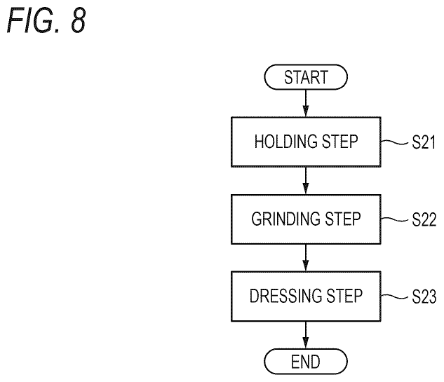

FIG. 8 is a flowchart illustrating an example of the processing method according to the second embodiment. The processing method according to the second embodiment includes a holding step S21 of holding the wafer 1 on the holding surface of the chuck table 60, a grinding step S22 of grinding the wafer 1 by the grinding wheel 64, and a dressing step S23 of dressing the grinding wheel 64.

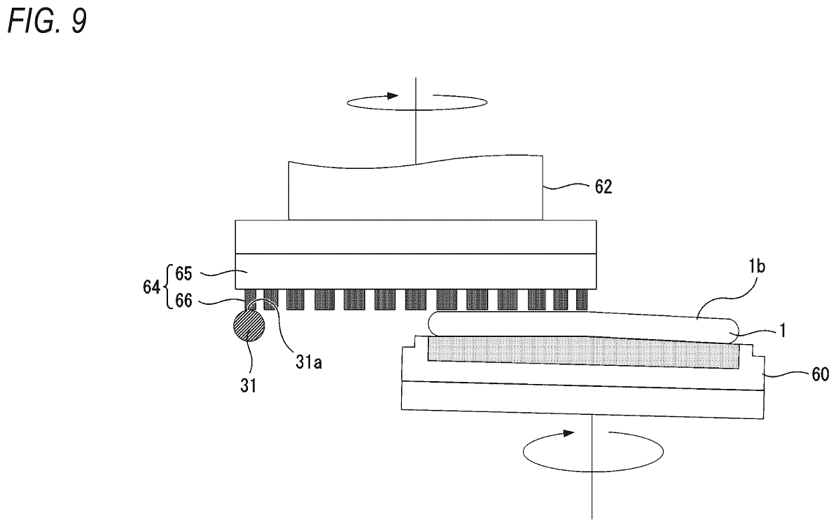

As illustrated in FIG. 9, in the grinding step S22, the back surface 1b of the wafer 1 held by the chuck table 60 is ground by the grindstones 66 of the grinding wheel 64 to thin the wafer 1. The grinding step S22 is performed by, for example, in-feed grinding. In the in-feed grinding, a positional relationship between the chuck table 60 and the grinding wheel 64 is adjusted such that a center of the wafer 1 held by the chuck table 60 coincides with a track of the grindstones 66. In the in-feed grinding, the grinding wheel 64 is lowered along a processing-feed direction (vertical direction) parallel to a rotation axis of the spindle 62 while rotating the chuck table 60 and the grinding wheel 64. Accordingly, a lower surface of the grindstones 66 comes into contact with the back surface 1b (upper surface) of the wafer 1, and the wafer 1 is ground.

In the dressing step S23, the grinding wheel 64 is dressed by bringing the dressing member 31, which contains abrasive grains and linearly stretches, into contact with the grinding wheel 64 while feeding the dressing member 31 in a stretching direction. Specifically, the dressing member 31 extends in a horizontal direction and is disposed in a position not overlapping the holding surface of the chuck table 60 when viewed in an upper-lower direction. The outer peripheral surface 31a of the dressing member 31 that extends in the stretching direction comes into contact with the grindstones 66 from the lower surface.

In this way, in the dressing step S23, the grinding wheel 64 is dressed while feeding the dressing member 31 in the stretching direction, and thus it does not take time or effort to replace the dressing member 31 as compared with a case where dressing is performed by carrying in and out a dressing board. Further, the grinding wheel 64 can be always dressed by the additionally fed dressing member 31.

Further, in the dressing step S23, since the linearly stretching dressing member 31 is brought into contact with the grinding wheel 64 while being fed in the stretching direction, the dressing step S23 can be performed during the grinding step S22. Therefore, time required for the dressing step S23 can be substantially zero.

In the dressing step S23, a feed speed of the dressing member 31 may be changed based on a processing status of the grinding step S22. For example, when clogging occurs in the grinding wheel 64 and a drive current value for rotating the grinding wheel 64 increases during the grinding step S22 and the dressing step S23, the controller 50 can change the feed speed of the dressing member 31 to eliminate the clogging of the grinding wheel 64. In this way, the wafer 1 can be appropriately dressed based on the processing status of the grinding step S22, and a processing quality can be kept constant.

The ground wafer 1 is conveyed to the cutting apparatus 2 and divided into a plurality of chips. Chips are manufactured accordingly.

In the second embodiment described above, the outer peripheral surface 31a of the dressing member 31 comes into contact with the grindstones 66 from the lower surface. Alternatively, as in the modification of the first embodiment described above, the distal end 31b of the dressing member 31 may come into contact with the grindstones 66 from the lower surface.

Although the embodiments of the present disclosure have been described above with reference to the accompanying drawings, it is needless to say that the present disclosure is not limited to the embodiments. It is obvious that those skilled in the art may come up with various changes or modification within the scope of the claims, and it is understood that these naturally fall within the technical scope of the present disclosure. In addition, components in the above-described embodiments may be freely combined without departing from the gist of the disclosure.

For example, in each of the embodiments described above, the dressing steps S13 and S23 are performed during the cutting step S12 or the grinding step S22, and the present disclosure is not limited thereto. For example, the dressing steps S13 and S23 may be performed at a freely selected timing before and after the cutting step S12 or the grinding step S22.

The present specification describes at least following matters. Corresponding components and the like in the above-described embodiments are shown in parentheses as an example, and the present disclosure is not limited thereto.

(1) A processing method including:
holding (holding steps S11 and S21) a workpiece (wafer 1) on a holding surface of a holding table (chuck table 10 and 60);
processing (cutting step S12 and grinding step S22) the workpiece by a grindstone tool (cutting blade 23 and grinding wheel 64); and
dressing (dressing steps S13 and S23) the grindstone tool by bringing a dressing member (dressing member 31), the dressing member containing abrasive grains and linearly stretching, into contact with the grindstone tool while feeding the dressing member in a stretching direction.

According to (1), in the dressing, the grindstone tool is dressed by bringing the linearly stretching dressing member into contact with the grindstone tool while feeding the dressing member in the stretching direction, which can thus save time and effort for carrying in and out a dressing board.

(2) The processing method according to (1), wherein
the dressing is performed during the processing.

According to (2), the dressing is performed during the processing, and thus time required for the dressing can be substantially zero.

(3) The processing method according to (2), wherein
the dressing includes changing a feed speed of the dressing member based on a processing status of the processing.

According to (3), the workpiece can be appropriately dressed based on the processing status of the processing, and a processing quality can be kept constant.

(4) The processing method according to any one of (1) to (3), wherein
the dressing step includes dressing the grindstone tool by bringing an outer peripheral surface (outer peripheral surface 31a) of the dressing member that extends in the stretching direction into contact with the grindstone tool.

According to (4), a contact area between the dressing member and the grindstone tool can be made relatively large, and thus the grindstone tool can be stably dressed.

(5) A chip manufacturing method for dividing a substrate (wafer 1) into a plurality of chips, the substrate (wafer 1) including devices (devices D) formed in respective regions partitioned by a plurality of planned dividing lines (planned dividing lines L), the chip manufacturing method including:
holding (holding step S11) the substrate on a holding table (chuck table 10);
cutting (cutting step S12) the substrate along the planned dividing lines by a cutting blade (cutting blade 23) including a grindstone; and
dressing (dressing step S13) the cutting blade by bringing a dressing member (dressing member 31) into contact with the cutting blade while feeding the dressing member in a stretching direction, the dressing member containing abrasive grains and stretching linearly.

According to (5), in the dressing, the cutting blade is dressed by bringing the linearly stretching dressing member into contact with the cutting blade while feeding the dressing member in the stretching direction, which can thus save time and effort for carrying in and out a dressing board. As a result, productivity of final chips can be improved.

(6) A chip manufacturing method for dividing a substrate (wafer 1) into a plurality of chips, the substrate (wafer 1) including devices (devices D) formed in respective regions partitioned by a plurality of planned dividing lines (planned dividing lines L), the chip manufacturing method including:
holding (holding step S21) the substrate on a holding table (chuck table 60);
grinding (grinding step S22) the substrate by a grinding wheel (grinding wheel 64) including a grindstone;
dressing (dressing step S23) the grinding wheel by bringing a dressing member (dressing member 31) into contact with the grinding wheel while feeding the dressing member in a stretching direction, the dressing member containing abrasive grains and linearly stretching; and
cutting (cutting step S12) the substrate along the planned dividing lines by a cutting blade (cutting blade 23).

According to (6), in the dressing, the grinding wheel is dressed by bringing the linearly stretching dressing member into contact with the grinding wheel while feeding the dressing member in the stretching direction, which can thus save time and effort for carrying in and out a dressing board. As a result, productivity of final chips can be improved.

(7) A dressing member (dressing member 31) for dressing a grindstone tool (cutting blade 23 and grinding wheel 64), wherein
the dressing member contains abrasive grains at least on an outer surface (outer peripheral surface 31a and distal end 31b), has a linearly stretching shape, and dresses the grindstone tool when the outer surface is brought into contact with the grindstone tool.

According to (7), the grindstone tool can be dressed using the linear dressing member without carrying a dressing board into or out of the processing apparatus.

(8) The dressing member according to (7), wherein
the dressing member is formed of a flexible material and is deformable.

According to (8), the dressing member can be managed in a wound state. In addition, a degree of freedom in routing the dressing member can be increased.

1. A processing method comprising:
holding a workpiece on a holding surface of a holding table;
processing the workpiece by a grindstone tool; and
dressing the grindstone tool by bringing a dressing member into contact with the grindstone tool while feeding the dressing member in a stretching direction, the dressing member containing abrasive grains and linearly stretching.

2. The processing method according to claim 1, wherein
the dressing is performed during the processing.

3. The processing method according to claim 2, wherein
the dressing comprises changing a feed speed of the dressing member based on a processing status of the processing.

4. The processing method according to claim 1, wherein
the dressing comprises dressing the grindstone tool by bringing an outer peripheral surface of the dressing member that extends in the stretching direction into contact with the grindstone tool.

5. A chip manufacturing method for dividing a substrate into a plurality of chips, the substrate including devices formed in respective regions partitioned by a plurality of planned dividing lines, the chip manufacturing method comprising:
holding the substrate on a holding table;
cutting the substrate along the planned dividing lines by a cutting blade including a grindstone; and
dressing the cutting blade by bringing a dressing member into contact with the cutting blade while feeding the dressing member in a stretching direction, the dressing member containing abrasive grains and linearly stretching.

6. A chip manufacturing method for dividing a substrate into a plurality of chips, the substrate including devices formed in respective regions partitioned by a plurality of planned dividing lines, the chip manufacturing method comprising:
holding the substrate on a holding table;
grinding the substrate by a grinding wheel including a grindstone;
dressing the grinding wheel by bringing a dressing member into contact with the grinding wheel while feeding the dressing member in a stretching direction, the dressing member containing abrasive grains and linearly stretching; and
cutting the substrate along the planned dividing lines by a cutting blade.

7. A dressing member for dressing a grindstone tool, wherein
the dressing member contains abrasive grains at least on an outer surface,
the dressing member has a linearly stretching shape, and
the dressing member dresses the grindstone tool when the outer surface is brought into contact with the grindstone tool.

8. The dressing member according to claim 7, wherein
the dressing member is formed of a flexible material and is deformable.
